(19) United States
(12) Patent Application Publication
(10) Pub. No.: US 2007/0193617 A1
(43) Pub. Date: Aug. 23, 2007

(54) Exhaust heat recovery power generation device and automobile equipped therewith

(75) Inventor: Tomonari Taguchi, Aichi-ken (JP)

Correspondence Address: OLIFF & BERRIDGE, PLC, P.O. BOX 19928, ALEXANDRIA, VA, 22320, US

(73) Assignee: Toyota Jidosha Kabushiki Kaisha, Aichi-ken (JP)

(21) Appl. No.: 10/591,858

(22) PCT Filed: Mar. 7, 2005
(86) PCT No.: PCT/JP05/04383

§ 371 Date: Sep. 6, 2006

(30) Foreign Application Priority Data
Apr. 7, 2004 (JP) 2004-113361

(51) Int. Cl. H01L 35/28

(52) U.S. Cl. 136/204

(57) ABSTRACT

An engine exhausts gas which is in turn exhausted through an exhaust pipe in a prescribed direction. A cooling water pump supplies cooling water to circulate a refrigerant through each of cooling water circulation paths. The cooling water circulation path includes a cooling water pipe arranged along the exhaust pipe to pass the cooling water. At stacks a plurality of thermoelectric power generation elements are attached to the exhaust pipe and the cooling water pipe successively in a direction from the upstream toward downstream of the exhaust gas. The cooling water pipe and the exhaust pipe pass the cooling water and the exhaust gas, respectively, in opposite directions so that the downstream stack has an increased difference in temperature between the exhaust pipe and the cooling water pipe, and the stacks provide power outputs having a reduced difference, and hence an increased total power output. Thus an exhaust heat recovery power generation device can provide increased thermoelectric conversion efficiency without complicated piping.

### TECHNICAL FIELD

The present invention relates to exhaust heat recovery power generation devices and particularly to exhaust heat recovery power generation devices receiving thermal energy of exhaust gas from a heat source such as an engine of a vehicle and converting the thermal energy to electrical energy, and automobiles equipped therewith.

### BACKGROUND ART

To achieve energy conservation, exhaust heat recovery power generation devices have conventionally been proposed that employ a thermoelectric conversion element to convert thermal energy contained in gas exhausted for example from automobile engines, factories and the like to electrical energy to effectively use the energy, as disclosed for example in Japanese Patent Laying-Open No. 61-2540 82. In particular, there have been proposed a configuration mounting such an exhaust heat recovery power generation device in a hybrid automobile to prevent reduced energy efficiency when an operation recovering waste energy has abnormality, as disclosed for example in Japanese Patent Laying-Open No. 2001-028805, and a configuration improving an attachment structure of a power generation module in an exhaust heat recovery power generation device to ensure that the module provides a sufficient output, as disclosed for example in Japanese Patent Laying-Open No. 2001-012240.

In particular, Japanese Patent Laying-Open No. 2001-012240 discloses an art applied to automobiles equipped with a thermoelectric power generation element having high power conversion efficiency as the power generation module has a high-temperature end pressed against and thus attached to an external surface of an exhaust pipe connected to an engine, and a low-temperature end cooled with cooling water to convert waste heat to electric power.

In the exhaust heat recovery power generation device for automobiles as disclosed in Japanese Patent Laying-Open No. 2001-012240 the exhaust pipe is internally provided with a heat recovery fin, which is arranged more densely downstream of the pipe to control the thermoelectric power generation element's high-temperature end to have a constant temperature to ensure that the engine's low-output range also allows a sufficient power output. Furthermore, the fin also functions as a reinforcement member in pressing and thus attaching the thermoelectric power generation element.

However, such a structure, provided with a large number of fins, prevents exhaust gas from flowing smoothly and also entails complicated piping.

### DISCLOSURE OF THE INVENTION

The present invention contemplates an exhaust heat recovery power generation device and automobile equipped therewith providing increased thermoelectric conversion efficiency without complicated piping.

The present exhaust heat recovery power generation device includes an exhaust pipe, a cooling pipe, a refrigerant supply unit, and a plurality of thermoelectric power generation units. The exhaust pipe receives exhaust gas from a heat source and passes the exhaust gas in a prescribed direction. The cooling pipe is arranged along the exhaust pipe to pass a refrigerant for cooling the exhaust pipe. The refrigerant supply unit supplies the cooling pipe with the refrigerant. The plurality of thermoelectric power generation units are attached to the exhaust pipe and the cooling pipe sequentially in a direction in which the exhaust gas flows. The plurality of thermoelectric power generation units each generate power corresponding to a difference in temperature between a high-temperature end and a low-temperature end thereof attached to the exhaust pipe and the cooling pipe, respectively, at a corresponding site. The refrigerant supply unit supplies the refrigerant in such a direction that the exhaust pipe and the cooling pipe pass the exhaust gas and the refrigerant, respectively, in opposite directions.

Preferably, the plurality of thermoelectric power generation units each include a plurality of thermoelectric power generation elements formed sequentially in the direction in which the exhaust gas flows, and the high-temperature end and low-temperature end are attached to the exhaust pipe and the cooling pipe, respectively, at a corresponding site.

Preferably each of the thermoelectric power generation elements is arranged to be sandwiched between the exhaust pipe and the cooling pipe.

The present automobile includes the exhaust heat recovery power generation device as recited in any of claims 1-3, a first driving force generation device, a source of electric power, and a second driving force generation device. The first driving force generation device uses a fuel's combustion energy as a source to generate wheel driving force. The exhaust heat recovery power generation device generates power with the first driving force generation device serving as the heat source. The second driving force generation device uses power generated by the exhaust heat recovery power generation device and that supplied from the source of electric power as a source to generate wheel driving force.

Preferably the source of electric power is a secondary battery and the exhaust heat recovery power generation device further includes a power converter converting the power generated by the exhaust heat recovery power generation device to voltage charging the secondary battery.

More preferably the automobile further includes a driving power conversion device converting received power to power driving the second driving force generation device and the exhaust heat recovery power generation device further includes a power converter converting the power generated by the exhaust heat recovery power generation device to power input to the driving power conversion.

Alternatively, preferably the automobile further includes a power generation device and a control device. The power generation device converts at least a portion of the wheel driving force generated by the first driving force generation device to power usable as power driving the second driving force generation device. The control device is provided to drive the automobile in accordance with a driver's instructions. The source of electric power is a secondary battery and the control device considers vehicle requirement power calculated in accordance with the driver's instructions and required to run the vehicle and charge requirement power for maintaining a level of charge of the secondary battery and in addition thereto power generated by the exhaust heat recovery power generation device to control the first driving force generation device's operation.

The present exhaust heat recovery power generation device allows a cooling pipe arranged along an exhaust pipe and the exhaust pipe to pass a refrigerant and exhaust gas, respectively, in opposite directions to ensure a power output generated at a thermoelectric power generation element located downstream of the exhaust gas, as compared with an arrangement with the refrigerant and the exhaust gas flowing in the same direction. As a result, the thermoelectric power generation elements can provide an increased total power output. Improved power generation efficiency can thus be achieved.

Furthermore, the thermoelectric power generation elements can be arranged to be sandwiched between the exhaust pipe and the cooling pipe and hence attached efficiently.

The present automobile can apply the exhaust heat recovery power generation device of any of claims 1-3 to a hybrid system capable of driving a wheel by both the first driving force generation device (an engine) and a second driving force generation device (a motor) to highly efficiently recover electrical energy from thermal energy of gas exhausted from the first driving force generation device (the engine). The vehicle's energy efficiency can be improved to achieve improved fuel efficiency.

In particular, the power generated by the exhaust heat recovery power generation device can be used as power to charge a source of electric power (a battery) or that input to a device (an inverter) generating power to drive the second driving force generation device (the motor).

Furthermore, vehicle requirement power and battery charge requirement power for a secondary battery are considered to control the first driving force generation device's (or engine's) operation and the exhaust heat recovery power generation device's power output can also be reflected to provide such control so that the exhaust heat recovery power generation device's improved power generation efficiency can more directly be reflected in improving the vehicle's fuel efficiency.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram generally showing a configuration of a hybrid system of an automobile equipped with the present exhaust heat recovery power generation device.

FIG. 2 is a block diagram showing a configuration of the present exhaust heat recovery power generation device in an embodiment.

FIG. 3 is a cross section taken along a line III-III in FIG. 2.

FIG. 4 is a block diagram showing a configuration of an exhaust heat recovery power generation device shown as a comparative example.

FIG. 5 illustrates a difference in temperature between the high-temperature and low-temperature ends of a thermoelectric power generation element at each stack.

FIG. 6 illustrates a power output at each stack.

FIG. 7 is a block diagram showing another exemplary configuration of the hybrid system of the automobile equipped with the present exhaust heat recovery power generation device.

### BEST MODES FOR CARRYING OUT THE INVENTION

Hereinafter the present invention in an embodiment will be described more specifically with reference to the drawings. Throughout the specification, identical or like components are identically denoted.

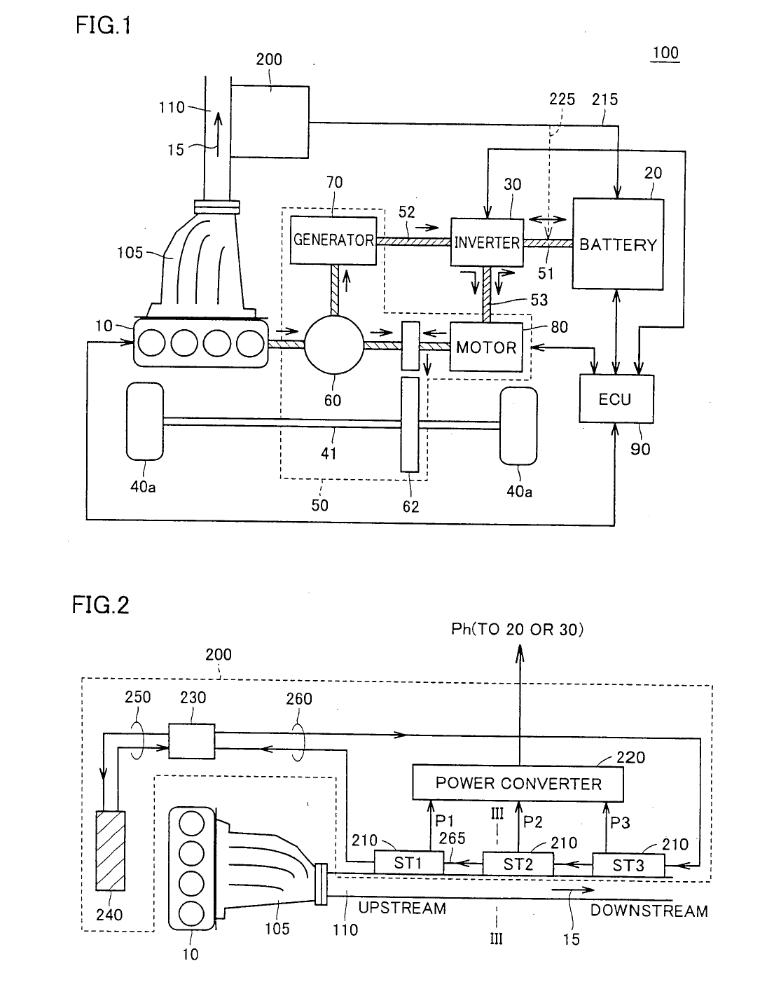

FIG. 1 is a block diagram generally showing a configuration of a hybrid system 100 of an automobile equipped with the present exhaust heat recovery power generation device.

With reference to FIG. 1, the present embodiment's hybrid system 100 includes an engine 10, a battery 20, an inverter 30, a wheel 40a, a transaxle 50, an electric control unit (ECU) 90, an exhaust manifold 105, an exhaust pipe 110, and an exhaust heat recovery power generation device 200.

Engine 10 uses gasoline or similar fuel's combustion energy as a source to generate force driving wheel 40a. More specifically, engine 10 corresponds to a “first driving force generation device” of the present invention. Furthermore, engine 10 also acts as a “heat source” in the present invention. Exhaust manifold 105 collects exhaust gas 15 from engine 10 and delivers exhaust gas 15 to exhaust pipe 110. Exhaust pipe 110 exhausts exhaust gas 15 in a prescribed direction.

Battery 20 operates as a “source of electric power “to supply a power line 51 with a direct current (dc) power. Battery 20 is implemented by a chargeable secondary battery. Representatively, a nickel-hydrogen storage battery, lithium ion secondary battery, or the like is applied.

Inverter 30 receives the dc power on power line 51, converts the power to an alternate current (ac) power, and outputs the power on a power line 53. Alternatively, inverter 30 receives ac power on lines 52, 53, converts the power to dc power, and outputs the power on line 51.

Transaxle 50 includes a transmission and an axle in an integral structure and has a force division mechanism 60, a reduction gear 62, a generator 70, and a motor 80.

Force division mechanism 60 is capable of dividing the driving force generated by engine 10 to a route transmitting the force via reduction gear 62 to axle 41 for driving wheel 40a, and a route transmitting the force to generator 70.

Generator 70 generates power as it is rotated by the driving force generated by engine 10 and transmitted via force division mechanism 60. Generator 70 generates power, which is supplied on power line 52 to inverter 30 and used as power charging battery 20 or that driving motor 80. Generator 70 corresponds to a “power generation device” of the present invention.

Motor 80 is driven rotatively by ac power supplied from inverter 30 on power line 53. Inverter 30 corresponds to a “driving power conversion device” in the present invention.

Motor 80 generates a driving force which is transmitted via reduction gear 62 to axle 41. Motor 80 corresponds to a “second driving force generation device” generating wheel driving force.

Furthermore, if in a regenerative braking operation motor 80 is rotated as wheel 40a is decelerated, motor 80 generates electromotive force (ac power) which is supplied to power line 53.

ECU 90 generally controls operation of equipment and circuit groups mounted in an automobile having hybrid system 100 mounted therein to allow the automobile to be driven in accordance with the driver's instructions. Representatively, ECU 90 is implemented for example by a microcomputer operating to execute a previously programmed, prescribed sequence and prescribed operation.

Thus in a hybrid automobile having hybrid system 100 mounted therein wheel 40a can be driven by both the driving force generated by engine 10 and that generated by motor 80.

Exhaust heat recovery power generation device 200 generates power such that thermal energy of gas exhausted from engine 10 and extracted through exhaust pipe 110, serves as a source. The power generated by exhaust heat recovery power generation device 200 is employed to charge battery 20, as indicated by a route 215, or directly supplied to inverter 30, as indicated by a route 220, to finally serve as a portion of a source of the wheel driving force generated by motor 80.

Note that, although not shown, battery 20 can supply power to inverter 30 associated with driving motor 80 as well as other equipment and circuits. More specifically, the power generated by exhaust heat recovery power generation device 200 can also be used via charging battery 20 as power driving any equipment and circuit mounted in the automobile. Alternatively, the power generated by exhaust heat recovery power generation device 200 can directly be supplied to other equipment and circuits through a route other than that shown in FIG. 1.

Exhaust heat recovery power generation device 200 is configured, as will be described later more specifically.

In hybrid system 100 when the automobile is started and runs at low speeds or drives down gentle hills or experiences similar light loads, engine 10 is not operated and the automobile is run by the driving force generated by motor 80 to avoid a poor engine efficiency range.

When the automobile normally runs, engine 10 outputs driving force which is divided by force division mechanism 60 into force driving wheel 40a and that driving generator 70 for power generation. The power generated by generator 70 is used to drive motor 80. As such, when the automobile normally runs, the driving force by engine 10 is assisted by that by motor 80 to drive wheel 40a. ECU 90 controls a force division ratio of force division mechanism 60 to achieve maximized general efficiency.

For full throttle acceleration, the power supplied from battery 20 is further employed to drive motor 80 to further increase the power driving wheel 40a.

In decelerating and braking the automobile, motor 80 is rotatively driven by wheel 40a to act as a power generator. Power recovered by regenerative power generation by motor 80 is used to charge battery 20 via power line 50, inverter 30 and power line 51.

When the vehicle stops, engine 10 is automatically stopped.

Thus the present invention in an embodiment provides hybrid system 100 combining for example the driving force generated by an engine 10 and that generated by motor 80 using electrical energy as a source to provide improved fuel efficiency.

ECU 90 controls the operation of engine 10 and motor 80 in accordance with the condition of the vehicle. In particular, ECU 90 provides control so that battery 20 maintains a constant charged state, and when for example by monitoring a state-of-charge (SOC) value ECU 90 detects a reduction in the amount of electricity charged in the battery, in addition to the above described basic conditions in which engine 10 and motor 80 are operated, engine 10 is operated to charge battery 20 by driving generator 70.

Electrical energy obtained by the present exhaust heat recovery power generation device 200 from thermal energy of exhaust gas 15 is recovered in hybrid system 100 as power charging battery 20 or that input to inverter 30. As such, providing improved thermoelectric power generation efficiency of exhaust heat recovery power generation device 200 provides improved energy efficiency in the entirety of an automobile having hybrid system 100 mounted therein.

The present exhaust heat recovery power generation device 200 is configured, as described hereinafter, to provide improved thermoelectric power generation efficiency.

FIG. 2 is a block diagram showing a configuration of the present exhaust heat recovery power generation device 200 in an embodiment.

With reference to FIG. 2, the “heat source” or engine 10 exhausts gas 15 which is in turn recovered in exhaust manifold 105 and then exhausted through exhaust pipe 110 in a prescribed direction.

Exhaust heat recovery power generation device 200 has a plurality of stacks 210 attached to exhaust pipe 110, a power converter 220, a cooling water pump 230, a cooling water radiator 240, and cooling water circulation paths 250, 260.

Cooling water pump 230, corresponding to a “refrigerant supply unit” in the present invention, supplies a refrigerant to circulate the refrigerant through each of coolant water circulation paths 250, 260. Representatively, the refrigerant is water, and hereinafter the refrigerant will be referred to as “cooling water.” Cooling water circulation paths 250, 260 pass cooling water in directions indicated in the figure by arrows written on the paths.

Cooling water circulation path 260 includes a cooling water pipe 265 arranged along exhaust pipe 110 and passing the cooling water therethrough. Cooling water pipe 265 corresponds to a “cooling pipe” in the present invention.

The plurality of stacks 210 are arranged along exhaust gas 150 from upstream toward downstream sequentially. In the FIG. 2 exemplary configuration, stacks ST1, ST2, ST3 are successively arranged along the exhaust gas 15 upstream toward downstream. Stacks 210 are similarly structured.

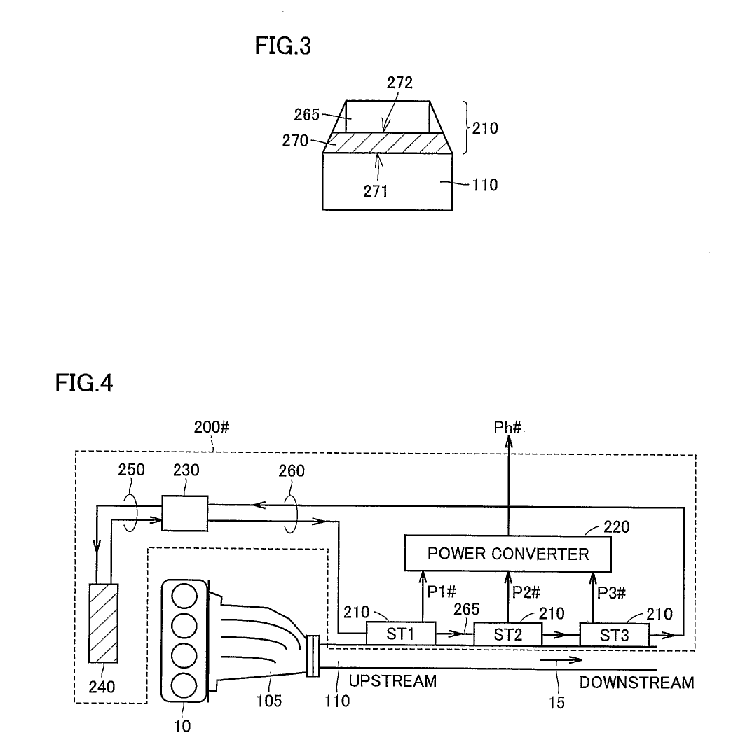

With reference to FIG. 3, at each stack 210 a thermoelectric power generation element 270 is attached such that a high-temperature end 271 is in contact with exhaust pipe 110 and a low-temperature end 272 is in contact with cooling water pipe 265. Thus a plurality of thermoelectric power generation elements 270 are attached to exhaust pipe 110 and cooling water pipe 265 from the exhaust gas 15 upstream toward downstream successively.

Thermoelectric power generation element 270 generates power corresponding to a difference in temperature between high-temperature end 271 and low-temperature end 272. As such, thermoelectric power generation elements 270 attached to exhaust pipe 110 from upstream toward downstream successively each generate power corresponding to a difference in temperature between exhaust pipe 110 and cooling water pipe 265 of the corresponding site.

Note that as shown in FIG. 3, arranging thermoelectric power generation element 270 such that it is sandwiched between exhaust pipe 110 and cooling water pipe 265 allows thermoelectric power generation element 270 to be efficiently attached.

With reference again to FIG. 2, the stacks ST1-ST3 thermoelectric power generation elements 270 generate powers P1-P3, which are converted by power converter 220 to power Ph which is used as power charging battery 20 or directly input to inverter 30, as has been shown in FIG. 1. In other words, power converter 220 converts powers P1-P3 generated and received from stacks ST1-ST3 to power charging battery 20 or that input to inverter 30.

The cooling water cools the exhaust pipe mainly in passing through cooling water pipe 265 to deprive exhaust gas 15 of heat to reduce the gas's temperature.

The cooling water circulated through cooling water circulation path 260 is increased in temperature, and delivered to cooling water circulation path 250 and has its heat discharged by radiator 240. The cooling water circulated through cooling water circulation path 260 is again delivered to cooling water circulation path 250 and used to cool exhaust gas 15.

The present exhaust heat recovery power generation device 200 is designed so that cooling water pipe 265 and exhaust pipe 110 pass the cooling water and exhaust gas 15, respectively, in opposite directions.

More specifically, cooling water circulation path 260 is designed so that the cooling water output from cooling water pump 230 passes through cooling water pipe 265 in a direction from stack ST3 downstream of exhaust pipe 110 toward stack ST1 upstream thereof to flow initially past stack ST3, then ST2, and finally STI.

FIG. 4 shows an exhaust heat recovery power generation device 200# having a different cooling water circulation path, as shown as a comparative example.

With reference to FIG. 4, exhaust heat recovery power generation device 200# is different from the FIG. 2 exhaust heat recovery power generation device 200 in that cooling water pipe 265 passes cooling water in the same direction as exhaust pipe 110 passes exhaust gas 15. The remainder of exhaust heat recovery power generation device 200# is similar to that of the FIG. 2 exhaust heat recovery power generation device 200.

More specifically in exhaust heat recovery power generation device 200# cooling water pump 230 is arranged so that the cooling water passes through cooling water pipe 265 in a direction from stack ST1 located upstream of exhaust gas 15 toward stack ST3 located downstream thereof to flow initially past stack ST1, then ST2, and finally ST3.

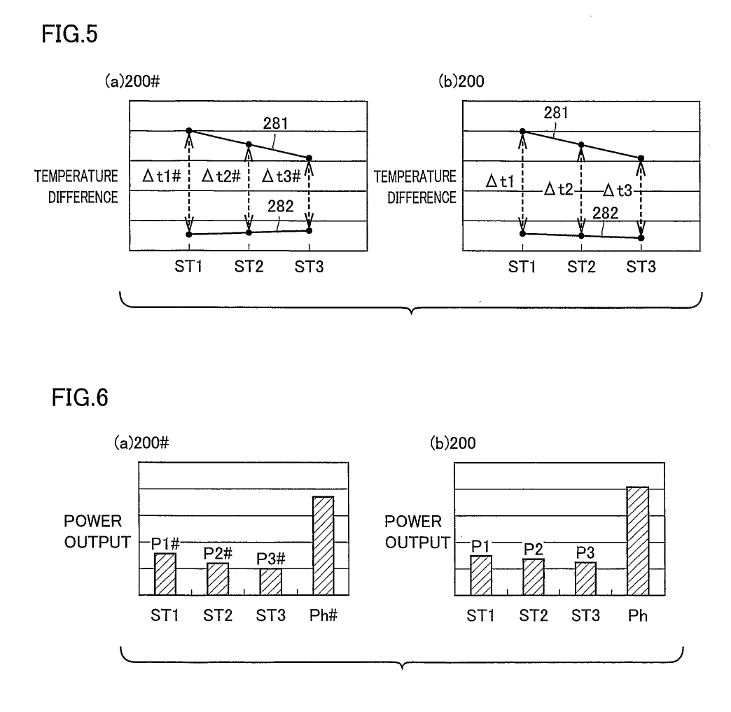

FIG. 5(a) represents a difference in temperature between the high-temperature and low-temperature ends of the thermoelectric power generation element located at each of stacks ST1-ST3 of exhaust heat recovery power generation device 200#, and FIG. 6(a) represents a power output provided at each stack by the difference in temperature indicated in FIG. 5(a).

In exhaust heat recovery power generation device 200# exhaust pipe 110 and cooling water pipe 265 pass exhaust gas 15 and the cooling water, respectively, in the same direction. As such, low-temperature end 272 in contact with cooling water pipe 265 has a temperature 282 increasing from stacks ST1 toward ST3. By contrast, high-temperature end 271 in contact with exhaust pipe 110 has a temperature 281 decreasing from stacks ST1 toward ST3.

As a result, the high-temperature end's temperature 281 and the low-temperature end's temperature 282 provide differences in temperature Δt1#, Δt2#, Δt3# having a large variation therebetween. More specifically, the stack (ST3) located downstream of the exhaust pipe can hardly ensure the difference in temperature Δt3#.

By contrast, FIG. 5(b) represents a difference in temperature between the high-temperature and low-temperature ends of the thermoelectric power generation element located at each of stacks ST1-ST3 of the present exhaust heat recovery power generation device 200, and FIG. 6(b) represents a power output provided at each stack by the difference in temperature indicated in FIG. 5(b).

In exhaust heat recovery power generation device 200 exhaust pipe 110 and cooling water pipe 265 pass exhaust gas 15 and the cooling water, respectively, in opposite directions. As such, low-temperature end 272 in contact with cooling water pipe 265 has temperature 282 decreasing from stacks ST1 toward ST3, similarly as observed in exhaust heat recovery power generation device 200#. By contrast, high-temperature end 271 in contact with exhaust pipe 110 has temperature 281 decreasing from stacks STI toward ST3.

As such, the high temperature end's temperature 281 and the low-temperature end's temperature 282 provide differences in temperature Δt1, Δt2, Δt3 with a reduced variation, and the stack (ST3) located downstream of exhaust pipe 110 can also ensure the difference in temperature Δt3.

As a result, as shown in FIG. 6(a), the comparative, exemplary exhaust heat recovery power generation device 200# has stacks ST1-ST3 providing power outputs P1#-P3# with a large variation, and cannot ensure that the downstream stack ST3# in particular provides sufficient power output, and hence a large power output Ph#.

By contrast, as shown in FIG. 6(b), the present exhaust heat recovery power generation device 200 ensures that the downstream stack ST3 thermoelectric power generation element also provides the difference in temperature Δt3. Stacks ST1-ST3 can provide power outputs P1-P3 with a reduced variation so that the total power output Ph can be larger than Ph# of the comparative example. The present exhaust heat recovery power generation device can thus generate power more efficiently.

Furthermore, by the present exhaust heat recovery power generation device excellent in power generation efficiency, engine driving can be controlled, as described hereinafter, to provide a hybrid automobile with improved fuel efficiency.

As has been described with reference to FIG. 1, ECU 90 controls the engine 10 and motor 80 operation in accordance with the vehicle's condition. In particular, the SOC value is for example monitored and used to keep battery 20 to have a specified charged level, and to do so ECU 90 calculates engine power Pe required for engine 10. Total engine power Pe calculated in accordance with the following expressions is used to control engine 10 to operate/stop, and its output power provided when it operates.
Pe=Pv+Pb (1)
Pb=Pchg+Psm−Ph (2)
wherein Pv represents engine power required to drive the vehicle calculated in accordance with a prescribed calculation preprogrammed in ECU 90 from the driver's operation typically represented by acceleration operation, a condition of the vehicle typically represented by the current vehicle speed, and the like, and Pb represents engine power required to charge the battery calculated as battery charge requirement power Pchg calculated in accordance with the SOC value plus power Psm lost for example at auxiliary minus power output Ph provided by exhaust heat recovery power generation device 200.

Thus vehicle requirement power Pv and battery charge requirement power Pchg for keeping battery 20 to have a charged state are considered to control engine 10 to operate/stop and the exhaust heat recovery power generation device's power output Ph can also be reflected to provide such control so that the exhaust heat recovery power generation device's improved power generation efficiency can more effectively contribute to less frequent operation of engine 10. The improvement in power generation efficiency of exhaust heat recovery power generation device 200 can thus be more directly reflected in improving the vehicle's fuel efficiency.

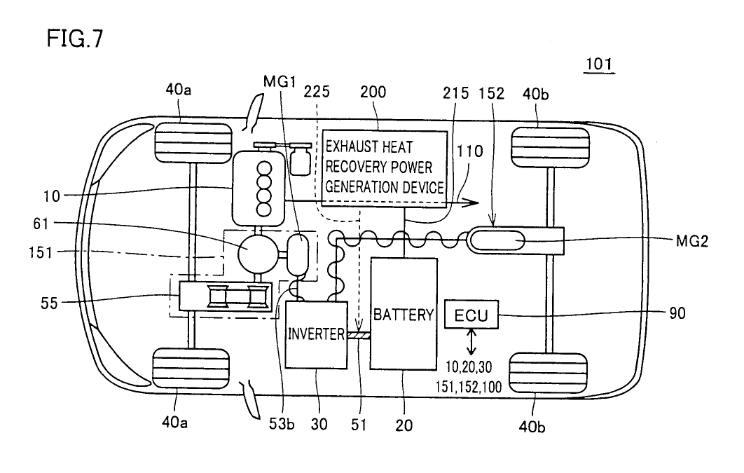

Note that the present exhaust heat recovery power generation device 200 can be applied not only to the FIG. 1 hybrid system but also a hybrid system 101 capable of four wheel drive, for example shown in FIG. 7.

FIG. 7 is a block diagram showing another exemplary configuration of a hybrid system of an automobile equipped with the present exhaust heat recovery power generation device.

With reference to FIG. 7, the present invention in another example provides a hybrid system 101 having a four wheel drive system capable of driving front and rear wheels 40a and 40b.

Hybrid system 101 has engine 10, battery 20, inverter 30, ECU 90, front and rear transaxles 151 and 152, respectively, and exhaust heat recovery power generation device 200.

Front transaxle 151 has a force division mechanism 61, a motor generator MG1, and a continuously variable transmission (CVT) 55. Motor generator MG1 has a function similar to that of motor 80 shown in FIG. 1 provided for driving wheel 40a. Force division mechanism 61 has a function similar to that of the FIG. 1 force division mechanism 60 to dispense the force received from engine 10 between a route providing the dispensed force as that driving wheel 40a via CVT 55 and a route providing the dispensed force as that driving motor generator MG1 for power generation.

Furthermore, motor generator MG1 can receive power from inverter 30 to rotate to generate driving force which can be provided via force division mechanism 60 to CVT 55 and thus used as force driving wheel 40a.

Rear transaxle 152 has a motor generator MG2 capable of receiving power from inverter 30 to drive rear wheel 40b.

Similarly as has been shown in the FIG. 1 configuration, battery 20 supplies power which is supplied on power line 51 to inverter 30. Furthermore, power generated by exhaust heat recovery power generation device 200 may be used to charge battery 20 via route 215 or can directly be input to inverter 30, as indicated by route 220.

Motor generators MG1 and MG2 in regenerative operation are rotated by wheels 40a, 40b to generate power. The generated power is converted by inverter 30 to dc power and used to charge battery 20.

In hybrid system 101 in starting the vehicle motor generators MG1, MG2 drive wheels 40a, 40b. If the vehicle experiences a light load as the vehicle runs in a poor engine efficiency range, engine 10 is stopped and front motor generator MG1 drives front wheel 40a to run the vehicle.

When the vehicle normally runs, the vehicle runs within a good engine efficiency range, and basically, the engine 10 power drives front wheel 40a to run the vehicle. if in doing so battery 20 is insufficiently charged, the driving force of engine 10 is used, as required, to drive motor generator MG1 as a power generator to charge battery 20.

For fill throttle acceleration, the engine 10 output is increased and the CVT's transmission ratio is increased to provide acceleration. Furthermore, motor generator MG1 assists wheel driving force to provide increased acceleration force. Furthermore, as required, rear motor generator MG2 drives rear wheel 40b to provide further enhanced acceleration.

When the vehicle is braked and decelerated, motor generators MG1, MG2 are actuated as a power generator to recover kinetic energy to charge battery 20.

Furthermore when the vehicle runs on a road having a small coefficient of friction (μ), the system operates in response for example to a detected slippery of front wheel 40a to actuate front motor generator MG1 as a power generator to generate power which is in turn utilized to drive rear motor generator MG2 to provide four wheel drive (4WD) to ensure that the vehicle runs with stability.

If in doing so motor generator MG1 provides a power output insufficient to drive motor generator MG2, battery 20 supplies power to operate motor generator MG2.

Hybrid system 101 also has ECU 90 controlling engine 10 to operate/stop and its output power as based on vehicle requirement power depending on the vehicle's condition and battery power calculated to keep battery 20 to have a charged state, and the present, highly efficient exhaust heat recovery power generation device can be used to effectively reduce the engine's operation frequency and output power to achieve improved fuel efficiency.

The present invention in an embodiment has been described with an example mounting the present exhaust heat recovery power generation device in a hybrid automobile. However, the present invention is not limited in application to the above-described embodiment. More specifically, the present exhaust heat recovery power generation device can be mounted in hybrid automobiles of any other configurations to effectively recover their engines' exhaust heat as electrical energy to achieve improved fuel efficiency. Furthermore, the present exhaust heat recovery power generation device can be applied not only to hybrid automobiles but also a system including an exhaust pipe receiving exhaust gas from a heat source to guide the exhaust gas in a prescribed direction and a cooling water pipe extending parallel to the exhaust pipe commonly to recover heat more efficiently.

Although the present invention has been described and illustrated in detail, it is clearly understood that the same is by way of illustration and example only and is not to be taken by way of limitation, the spirit and scope of the present invention being limited only by the terms of the appended claims.

### INDUSTRIAL APPLICABILITY

The present exhaust heat recovery power generation device is applicable to exhaust heat recovery power generation in equipment/systems including a heat source, including automobiles having an internal combustion engine.

1. An exhaust heat recovery power generation device comprising:
an exhaust pipe receiving exhaust gas from a heat source and passing the exhaust gas in a prescribed direction;
a cooling pipe arranged along said exhaust pipe to pass a refrigerant for cooling said exhaust pipe;
a refrigerant supply unit supplying said cooling pipe with said refrigerant; and
a plurality of thermoelectric power generation stacks attached to said exhaust pipe and said cooling pipe sequentially in a direction in which said exhaust gas flows, wherein:
said plurality of thermoelectric power generation stacks each include a plurality of thermoelectric power generation elements formed sequentially in the direction in which said exhaust gas flows;
said plurality of thermoelectric power generation elements each generate power corresponding to a difference in temperature between a high-temperature end and a low-temperature end thereof, said high-temperature end and said low-temperature end being attached to said exhaust pipe and said cooling pipe, respectively, at a corresponding site; and
said refrigerant supply unit is configured to supply said refrigerant in such a direction that said exhaust pipe and said cooling pipe pass said exhaust gas and said refrigerant, respectively, in opposite directions.

2. (canceled)

3. The exhaust heat recovery power generation device of claim 1, wherein each of said thermoelectric power generation elements is arranged to be sandwiched between said exhaust pipe and said cooling pipe.

4. An automobile comprising:
a first driving force generation device using a fuel's combustion energy as a source to generate wheel driving force;
the exhaust heat recovery power generation device as recited in claim 1, said exhaust heat recovery power generation device generating power with said first driving force generation device serving as said heat source; and
a source of electric power; and
a second driving force generation device using power generated by said exhaust heat recovery power generation device and that supplied from said source of electric power as a source to generate wheel driving force.

5. The automobile of claim 4, wherein:
said source of electric power is a secondary battery; and
said exhaust heat recovery power generation device further includes a power converter converting the power generated by said exhaust heat recovery power generation device to voltage charging said secondary battery.

6. The automobile of claim 4, further comprising a driving power conversion device converting received power to power driving said second driving force generation device, wherein said exhaust heat recovery power generation device further includes a power converter converting the power generated by said exhaust heat recovery power generation device to power input to said driving power conversion device.

7. The automobile of claim 4, further comprising:
a power generation device converting at least a portion of said wheel driving force generated by said first driving force generation device to power usable as power driving said second driving force generation device; and
a control device operative to drive said automobile in accordance with a driver's instructions, wherein:
said source of electric power is a secondary battery; and
said control device considers vehicle requirement power Calculated in accordance with said driver's instructions and required to run the vehicle and charge requirement power for maintaining a level of charge of said secondary battery and in addition thereto power generated by said exhaust heat recovery power generation device to control said first driving force generation device's operation.

8. An automobile comprising:
a first driving force generation device using a fuel's combustion energy as a source to generate wheel driving force;
the exhaust heat recovery power generation device as recited in claim 3, said exhaust heat recovery power generation device generating power with said first driving force generation device serving as said heat source; and
a source of electric power; and
a second driving force generation device using power generated by said exhaust heat recovery power generation device and that supplied from said source of electric power as a source to generate wheel driving force.
